(19) United States
(12) Patent Application Publication
(10) Pub. No.: US 2014/0261184 A1
(43) Pub. Date: Sep. 18, 2014

(54) ORGANIC THIN FILM DEPOSITION SYSTEM AND METHOD FOR DEPOSITING ORGANIC FILM

(71) Applicant: Samsung Display Co., Ltd., Yongin-si (KR)

(72) Inventors: Yuji Hamada, Yongin-si (KR); Hye-In Jeong, Yongin-si (KR)

(73) Assignee: Samsung Display Co., Ltd., Yongin-si (KR)

(21) Appl. No.: 14/288,337

(22) Filed: May 27, 2014

Related U.S. Application Data
(63) Continuation of application No. 13/283,300, filed on Oct. 27, 2011.

(30) Foreign Application Priority Data
Jun. 14, 2011 (KR) 10-2011-0057671

(51) Int. Cl. H01L 51/56

(52) U.S. Cl. CPC H01L 51/56
USPC 118/727

(57) ABSTRACT

An organic thin film deposition system is disclosed. The organic thin film deposition system includes: a plurality of crucibles each having an inlet capable of selectively being opened and closed; an organic composite material made up of two or more organic materials and having an initial composition ratio, the organic composite material for placing in the plurality of crucibles; and a transferring unit for controlling a position of the plurality of crucibles.

### CROSS-REFERENCE TO RELATED APPLICATIONS

This application is a continuation of U.S. patent application Ser. No. 13/283,300, filed on Oct. 27, 2011, entitled Organic Thin Film Deposition System and Method for Depositing Organic Film, which claims priority to and the benefit of Korean Patent Application No. 10-2011-0057671, filed in the Korean Intellectual Property Office on Jun. 14, 2011, the entire content of all of which are incorporated herein by reference.

### BACKGROUND

1. Field

Aspects of embodiments of the present invention are directed toward an organic thin film deposition system used, for example, to form an organic light emitting diode (OLED) display, and a method for manufacturing an organic thin film.

2. Description of the Related Art

A process of depositing an organic thin film may be used to manufacture an organic light emitting diode (OLED) display. The organic thin film may be formed through a vacuum deposition method.

The above information disclosed in this Background section is only for enhancement of understanding of the background of the described technology and therefore it may contain information that does not form the prior art that is already known in this country to a person of ordinary skill in the art.

### SUMMARY

An exemplary embodiment of the present invention provides for an organic thin film deposition system that improves uniformity of an organic thin film. In addition, an exemplary embodiment of the present invention provides for a method of depositing organic thin film materials more uniformly for forming an organic thin film.

In an exemplary embodiment of the present invention, an organic thin film deposition system is provided. The organic thin film deposition system includes: an organic composite material including two or more organic materials and having an initial composition ratio; a plurality of crucibles each having an inlet capable of selectively being opened and closed, the plurality of crucibles being configured to receive the organic composite material; and a transferring unit for controlling a position of the plurality of crucibles.

The inlets of the plurality of crucibles may be configured to sequentially open and close.

The system may be configured: to close an opened inlet of a first crucible among the plurality of crucibles when a composition ratio of the organic composite material in the first crucible changes by more than a first amount from the initial composition ratio; and to open the inlet of a second crucible among the plurality of crucibles, the second crucible including the organic composite material having the initial composition ratio.

The system may be further configured to heat a crucible of the plurality of crucibles when the inlet of the crucible is open.

The first amount may be less than about 30% of the initial composition ratio.

The system may be further configured to place a crucible among the plurality of crucibles at a position corresponding to a center of an organic thin film deposition object substrate when the inlet of the crucible is open.

The plurality of crucibles may be arranged in a circle.

The transferring unit may be configured to rotate the plurality of crucibles.

The plurality of crucibles may be arranged in a line.

The transferring unit may be configured to linearly move the plurality of crucibles back and forth.

The system may further include a chamber including the plurality of crucibles.

The organic composite material may include a host material and a dopant material.

The dopant material may be included in a weight ratio of less than 10% with respect to the organic composite material.

The host material may include at least one of NPB (N,N′-diphenyl-N,N′-bis(1-naphthyl)-1,1′-biphenyl-4,4′-diamine), BAlq, m-BAlq, or CBP (4,4′-N, N′-dicarbazolbiphenyl).

The dopant material may include at least one of rubrene (5,6,11,12-tetraphenylnaphthacene), Ir(piq)3, or Ir(ppy)3.

According to another exemplary embodiment of the present invention, a method of depositing an organic thin film is provided. The method includes: providing a plurality of crucibles each having an inlet capable of selectively being opened and closed; placing an organic composite material comprising two or more organic materials having an initial composition ratio in the plurality of crucibles; opening the inlet of a first crucible among the plurality of crucibles; heating the first crucible; closing the inlet of the first crucible when a composition ratio of the organic material in the first crucible changes by more than a first amount from the initial composition ratio; opening the inlet of a second crucible among the plurality of crucibles, the second crucible comprising the organic composite material having the initial composition ratio; and heating the second crucible.

The method may further include placing a crucible among the plurality of crucibles at a position corresponding to a center of an organic thin film deposition object substrate when the inlet of the crucible is open.

The method may further include providing a chamber including the plurality of crucibles.

The first amount may be less than about 30% of the initial composition ratio.

The organic composite material may include: a host material including at least one of NPB (N,N′-diphenyl-N,N′-bis(1-naphthyl)-1,1′-biphenyl-4,4′-diamine), BAlq, m-BAlq, or CBP (4,4′-N,N′-dicarbazolbiphenyl); and a dopant material including at least one of rubrene (5,6,11,12-tetraphenylnaphthacene), Ir(piq)3, or Ir(ppy)3.

According to the exemplary embodiments of the present invention, an organic thin film deposition system and an organic thin film deposition method may improve the uniformity of a deposited organic thin film.

### BRIEF DESCRIPTION OF THE DRAWINGS

FIG. 1 is a top plan view of an organic thin film deposition system according to a first exemplary embodiment.

FIG. 2 is a flowchart of an organic thin film deposition method using the organic thin film deposition system shown in FIG. 1.

FIG. 3 is a top plan view of an organic thin film deposition system according to a second exemplary embodiment.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification. In exemplary embodiments other than the first exemplary embodiment, only elements different from those of the first exemplary embodiment may be described. Further, the size and thickness of each of the elements that are displayed in the drawings are illustrated for better understanding and ease of description, and the present invention is not limited by the shown size and thickness.

In exemplary embodiments according to the present invention, an organic thin film may be formed through a vacuum deposition method. The vacuum deposition method may, for example, include inserting an organic material into a deposition crucible made of tungsten in a high vacuum environment, and then heating the crucible. When the organic material in the heated crucible is vaporized under vacuum, a vapor of the organic material may contact an object substrate for an organic thin film deposition. As a result, the organic material vapor may deposit and solidify on the object substrate, thereby forming the organic thin film.

To improve efficiency of a light emitting mechanism of an organic light emitting element (organic light emitting diode, or OLED), doping may be used. For example, if a light emitting dopant is added to a host material of an emission layer, improved luminous efficiency may be obtained.

A co-deposition method may be used to add a dopant of an amount (for example, a predetermined amount) to a host material. In the co-deposition method, the host and the dopant may be placed in separated deposition crucibles whose temperatures are independently controlled. The deposition speed of the host and the dopant may then be measured, and a doping concentration determined according to a ratio (or percentage) thereof.

In some embodiments, the concentration of the dopant may be relatively low. Accordingly, accurate control of the deposition speed of the materials may become important. However, controlling the deposition speeds of a plurality of materials depending on predetermined ratios may be difficult, such that overall productivity may be deteriorated.

Another method of depositing the host and the dopant is to mix them before heating the crucible. When using this method, the deposition speeds of the plurality of organic materials need not be independently controlled, such that the deposition process may be greatly simplified.

However, when the host and the dopant are mixed prior to heating the crucible, the composition ratio of the mixture material may be changed during the time that the deposition process is executed. This is because the host and the dopant may have different vaporization temperatures. Accordingly, if the same deposition process is used for the mixed materials as for the separate materials, the composition ratio of the resulting thin film may be changed such that the organic thin film formed through the deposition becomes non-uniform.

Accordingly, an organic thin film deposition system 101 for more uniformly depositing a plurality of materials according to a first exemplary embodiment will be described with reference to FIG. 1.

The organic thin film deposition system 101 includes a plurality of crucibles 300 each having an inlet (or opening) capable of selectively being opened and closed, an organic composite material 200 placed inside the plurality of crucibles 300 (for example, in each of the crucibles 300), and a transferring unit 400 for controlling a position of the plurality of crucibles 300. Each crucible 300 used for deposition may include (or be made from) materials such as tungsten and structures disclosed in the prior art and known to those of ordinary skill in the art.

In some embodiments, the inlets of the plurality of crucibles 300 may be sequentially closed and opened. In FIG. 1, reference numeral 301 indicates a crucible having an opened inlet, and reference numeral 302 indicates a crucible having a closed inlet. In addition, the crucible 301 having the opened inlet is heated through various methods disclosed in the prior art and known to those of ordinary skill in the art.

The organic composite material 200 includes two or more organic materials with an initial composition ratio (for example, each of the materials makes up a percentage by weight of the total composition), and is placed in the plurality of crucibles 300 with the same composition ratio. For example, each of the plurality of crucibles 300 may receive a portion of the organic composite material 200.

In further detail, the organic composite material 200 includes at least one host material and at least one dopant material. For example, when forming the organic emission layer, the host material is a main material of the organic emission layer, and the dopant material is a material added at an amount (for example, a predetermined amount) to improve luminous efficiency of the organic emission layer. Here, the dopant material may be added at a weight ratio (weight percentage) of less than 10% with respect to the organic composite material 200. For example, the dopant may be added at a weight ratio of 5%.

The host material may include at least one of NPB (N,N′-diphenyl-N,N-bis(1-naphthyl)-1,1′-biphenyl-4,4′-diamine), BAlq, m-BAlq, or CBP (4,4′-N,N′-dicarbazolbiphenyl). That is, the host material may include a compound expressed by at least one of Chemical Formula 1 to Chemical Formula 4 below.

[chemical structure]

The dopant material may include at least one of rubrene (5,6,11,12-tetraphenylnaphthacene), Ir(piq)3, or Ir(ppy)3. That is, the dopant material may include a compound represented by at least one of Chemical Formula 5 to Chemical Formula 7 below.

[chemical structure]

The transferring unit 400 moves the opened inlet crucible 301 to a position corresponding to the center (or other intended location of the organic thin film) of an organic thin film deposition object substrate SB. In the exemplary embodiment of FIG. 1, the plurality of crucibles 300 are arranged in a circle. Consequently, the transferring unit 400 may, for example, rotate the plurality of crucibles 300 such that the opened inlet crucible 301 is moved to correspond to the center of the organic thin film deposition object substrate SB. Here, the plurality of crucibles 300 may all be located in the same chamber (for example, in the same vacuum chamber).

By using this design, the organic thin film deposition system 101 may improve the uniformity of the organic thin film formed through the deposition. In addition, the uniformity of the organic thin film deposited may be improved through an exemplary method using this deposition system.

In the method, the inlet of a crucible 301 of a plurality of crucibles 300 is first opened and the crucible 301 heated to deposit the organic composite material 200 located in the crucible 301. Then, if the composition ratio of the organic composite material 200 located in the heated crucible 301 changes, the inlet is closed and the inlet of another crucible 302 is opened and the crucible 302 heated. The determining of when the composition ratio of the organic composite material 200 changes may use methods or systems disclosed in the prior art and known to those of ordinary skill in the art.

Next, referring to FIG. 1 and FIG. 2, the operation process of the organic thin film deposition system 101, that is, an organic thin film deposition method using the organic thin film deposition system 101, will be described.

First, a plurality of crucibles 300 each having the inlet capable of selectively being closed and opened are provided (S100). Here, the plurality of crucibles 300 may be located in the same chamber. In addition, an organic composite material 200 made up of organic materials of two or more kinds is placed (for example, loaded) in the plurality of crucibles 300 with the same initial composition ratio (S200).

Next, the inlet of at least one of the plurality of crucibles 300 is opened, and the crucible is heated (S300) to deposit the organic composite material 200. Here, the crucible 300 having the opened inlet is located at (for example, moved to) a position corresponding to the center of an organic thin film deposition object substrate SB.

Next, if the composition ratio of the organic composite material 200 placed in the crucible 301 having the opened inlet changes by more than an amount (for example, a predetermined amount) compared with the initial composition ratio, the inlet of the crucible 301 having the opened inlet is closed. in addition, the inlet of at least one of the other crucibles 302 including the organic composite material 200 with the initial composition ratio is opened, and the corresponding crucible is heated (S400).

Here, the predetermined amount may be a range. For instance, the range may be within 30% (or within about 30%) of the initial composition ratio. For example, if the initial composition ratio of one of the organic materials is 10% and the predetermined range is 30%, the inlet of a first crucible among the plurality of crucibles is closed when the composition ratio of the organic material is 7% or 13%. In addition, the crucible 302 having the newly opened inlet is located at or moved to a position corresponding to the center of the organic thin film deposition object substrate SB.

The organic thin film is deposited by repeating the above-described process until the composition ratios of the organic composite material 200 placed in the plurality of crucibles 300 are all changed from the initial composition ratio.

By performing the above-described method, the uniformity of the deposited organic thin film may be improved.

Next, an organic thin film deposition system 102 according to a second exemplary embodiment will be described with reference to FIG. 3.

As shown in FIG. 3, in the organic thin film deposition system 102, a plurality of crucibles 300 are arranged in a line. In addition, the transferring unit 500 linearly moves (for example, shifts) the plurality of crucibles 300 back and forth. The transferring unit 500 moves the crucible 301 having the opened inlet among the plurality of crucibles 300 to correspond to the center of the organic thin film deposition object substrate SB.

By using this design, the organic thin film deposition system 102 may improve the uniformity of the deposited organic thin film.

While the present invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and equivalents thereof.

### DESCRIPTION OF SELECTED SYMBOLS

101, 102: organic thin film deposition system
200: organic composite material
300: plurality of crucibles
400, 500: transferring unit
SB: organic thin film deposition object substrate

1. (canceled)

2. A method of depositing an organic thin film, the method comprising:
providing a plurality of crucibles each having an inlet capable of selectively being opened and closed;
placing an organic composite material comprising two or more organic materials having an initial composition ratio in the plurality of crucibles; and
controlling a position of the plurality of crucibles by a transferring unit.

3. The method of claim 2, further comprising sequentially opening and closing the inlets of the plurality of crucibles.

4. The method of claim 2, further comprising:
opening the inlet of a first crucible among the plurality of crucibles;
heating the first crucible;
closing the inlet of the first crucible when a composition ratio of the organic materials in the first crucible changes by more than a first amount from the initial composition ratio;
opening the inlet of a second crucible among the plurality of crucibles, the second crucible comprising the organic materials having the initial composition ratio; and
heating the second crucible.

5. The method of claim 4, wherein the first amount is less than about 30% of a proportion of one of the organic materials in the initial composition ratio.

6. The method of claim 4, further comprising placing a crucible among the plurality of crucibles at a position corresponding to a center of an organic thin film deposition object substrate when the inlet of the crucible is open.

7. The method of claim 6, wherein the plurality of crucibles are arranged in a circle.

8. The method of claim 7, further comprising rotating the plurality of crucibles by the transferring unit.

9. The method of claim 6, wherein the plurality of crucibles are arranged in a line.

10. The method of claim 9, further comprising linearly moving the plurality of crucibles back and forth by the transferring unit.

11. The method of claim 2, further comprising providing a chamber comprising the plurality of crucibles.

12. The method of claim 2, wherein the organic composite material comprises a host material and a dopant material.

13. The method of claim 12, wherein the dopant material is included in a weight ratio of less than 10% with respect to the organic composite material.

14. The method of claim 12, wherein the host material comprises at least one of NPB (N,N′-diphenyl-N,N′-bis(1-naphthyl)-1,1′-biphenyl-4,4′-diamine), BAlq, m-BAlq, or CBP (4,4′-N,N′-dicarbazolbiphenyl).

15. The method of claim 12, wherein the dopant material comprises at least one of rubrene (5,6,11,12-tetraphenylnaphthacene), Ir(piq)3, or Ir(ppy)3.

16. A method of depositing an organic thin film, the method comprising:
providing a plurality of crucibles each having an inlet capable of selectively being opened and closed;
placing an organic composite material comprising two or more organic materials having an initial composition ratio in the plurality of crucibles;
opening the inlet of a first crucible among the plurality of crucibles;
heating the first crucible;
closing the inlet of the first crucible when a composition ratio of the organic material in the first crucible changes by more than a first amount from the initial composition ratio;
opening the inlet of a second crucible among the plurality of crucibles, the second crucible comprising the organic composite material having the initial composition ratio; and
heating the second crucible.

17. The method of claim 16, further comprising placing a crucible among the plurality of crucibles at a position corresponding to a center of an organic thin film deposition object substrate when the inlet of the crucible is open.

18. The method of claim 16, further comprising providing a chamber comprising the plurality of crucibles.

19. The method of claim 16, wherein the first amount is less than about 30% of a proportion of one of the organic materials in the initial composition ratio.

20. The method of claim 16, wherein the organic composite material comprises:
a host material comprising at least one of NPB (N,N′-diphenyl-N,N′-bis(1-naphthyl)-1,1′-biphenyl-4,4′-diamine), BAlq, m-BAlq, or CBP (4,4′-N,N′-dicarbazolbiphenyl); and
a dopant material comprising at least one of rubrene (5,6,11,12-tetraphenylnaphthacene), Ir(piq)3, or Ir(ppy)3.
